(19) United States
(12) Patent Application Publication
(10) Pub. No.: US 2009/0165841 A1
(43) Pub. Date: Jul. 2, 2009

(54) Collapsible Solar System

(76) Inventors: Ross Gunn, JR., Corona Del Mar, CA (US); Gary Baker, (US)

Correspondence Address: Ross Gunn Jr., P.O. Box 1818, Rancho Cucamonga, CA, 91729-1818, US

(21) Appl. No.: 11/966,991

(22) Filed: Dec. 29, 2007

(51) Int. Cl. H01L 31/045

(52) U.S. Cl. 136/245

(57) ABSTRACT

A collapsible solar system includes a frame structure and a sunlight tracking arrangement. The frame structure includes a supporting base adapted for mounting on a platform and a solar panel pivotally coupling with a rotational frame which is rotatably supported on the supporting base. The solar panel is pivotally folded between a stored position that the solar panel is laid flat on the platform, and a tracking position that the solar panel is pivotally folded at an inclination angle to be perpendicular to the direction of the sun. The sunlight tracking arrangement includes a horizontal driving unit selectively adjusting a horizontal direction of the solar panel, and a vertical driving unit pivotally lifting up the solar panel until the solar panel is pivotally folded at the inclination angle to be perpendicular to the direction of the sun.

### BACKGROUND

1. Field of the Invention

The present invention relates to a solar system. More particularly, a collapsible solar system comprises a solar panel adapted for automatically being folded to a stored position that the solar parted is overlapped on a platform and a tracking position that the solar panel is oriented in a bi-direction manner for solar energy collection.

2. Discussion of the Related Art

Photovoltaic panels, commonly called solar panels, generally comprise a plurality of interconnected modules, wherein each of the modules contains a plurality of photovoltaic cells to convert the radiant energy of sunlight directly into electrical energy. In order to effectively collect the radiant energy, the solar panel generally incorporates with a folding frame to adjust an inclination angle of the solar panel so that the solar panel can be adjusted to be perpendicular to the direction of the sun.

For residential or commercial buildings, the solar panel can be simply built at the roof of the building to collect the radiant energy. However, as it is mentioned above, the solar panel is stationary so that the solar panel cannot be moved towards the sun as the sun “moves”. The above mentioned folding frame is one of the best solutions to solve the drawback of the solar panel far the building. The folding frame generally comprises a pivot hinge to pivotally connect with the solar panel so that the solar panel is adapted to pivotally move at an inclination angle with respect to the ground or the roof to face towards the sun. However, such folding frame requires a complicated structure and the installation cost of the solar panel is relatively high.

### BRIEF SUMMARY OF THE INVENTION

The present invention overcomes the above mentioned drawbacks and limitation by providing a collapsible solar system to mount on a platform, especially on the roof of a recreational vehicle.

Accordingly, the present invention provides a collapsible solar system comprising a frame structure and a sunlight tracking arrangement. The frame structure comprises a supporting base adapted for mounting on a platform, a rotational frame supported on the supporting base, and a solar panel having a pivot edge pivotally coupling with a first edge of the rotational frame and an opposed controlling edge. The solar panel is adapted to pivotally fold between a stored position for transport and a tracking position for solar energy collection. The sunlight tracking arrangement comprises a horizontal driving unit and a vertical driving unit. The horizontal driving unit drives the rotational frame to be rotated on the supporting base so as to selectively adjust a horizontal direction of the solar panel in responsive to the direction of the sun. The vertical driving unit is arranged for pivotally lifting up the solar panel at the controlling edge thereof until the solar panel is pivotally folded at the inclination angle to be perpendicular to the direction of the sun, and pivotally dropping down the solar panel at the controlling edge thereof until the solar panel is pivotally folded to overlap on the rotational frame at the stored position.

Moreover, an elongated guiding arm is pivotally coupled with the rotational frame to guide the movement of the solar panel at the inclination angle. When the solar panel is folded flat on the platform, the guiding arm is horizontally supported above the solar panel to minimize the storing space of the guiding arm. At the tracking position of said solar panel, the guiding arm is pivotally lifted up at an inclined configuration, so that the solar panel is guided to slide along the inclined guiding arm so as to selectively adjust the inclination angle of the solar panel.

The primary objective of the present invention is to provide a collapsible solar system. More particularly, the solar panel is adapted for automatically being folded between a stored position that the solar panel is overlapped on the platform and a tracking position that the solar panel is oriented in a bi-direction manner to collect solar energy.

A portable solar device is also known, wherein the portable solar device comprises a portable frame supporting the solar panel and selectively adjust the inclination angle of the solar panel. The portable frame generally comprises a wheel base for manually moving the solar panel at the horizontal direction and a pivotal mechanism for pivotally moving the solar panel at the vertical direction. In other words, it is extremely inconvenient for the user that he or she must manually adjust the horizontal direction of the solar panel via the wheel base and the vertical directional of the solar panel via a hand crank of the pivotal mechanism. However, in order to enhance the portability of the solar device, the size of the portable frame is relatively small. Therefore, even though the solar panel can be adjusted its inclination angle to face towards the sun, only a small amount of radiant energy will be collected by the solar panel. In other words, the portable solar device can only be used for emergency purposes. Thus, the user must manually “move” the portable frame every hour to optimize the orientation of the solar panel to be perpendicular to the direction of the sun.

A major drawback of the above mentioned solar systems is mat none of the solar systems can be mounted to the recreational vehicle. Since the recreational vehicle travels from one location to another location, the solar panel must be folded flat on the roof during traveling and must be elevated to an optimum inclination angle for energy collection. Therefore, the solar panel is horizontally laid flat on the roof for most recreational vehicles.

The second objective of the present invention is to provide a collapsible solar system, wherein the solar panel can be completely folded flat on the roof of the recreational vehicle during traveling.

The third objective of the present invention is to provide a collapsible solar system, wherein the solar panel is driven to be rotated in a horizontal direction on a rotational frame infinitely so that no cable will be twisted up during tile rotational movement of the solar panel.

The fourth objective of the present invention is to provide a collapsible solar system, wherein tile solar panel is automatically moved to track the direction of the sun via a fight sensing unit so that the solar panel moves horizontally and vertically as the sun “moves”. In particularly, the light sensing unit comprises two light sensors for the vertical tracking axis and another two light sensors for the horizontal tracking aids. Each of the light sensors is mounted within a housing with an aperture that allows sunlight to fall on half of each light sensor when the sensor is “on axis” with the sun. By using the two light sensors per axis, the tracking system gain is doubled over the conventional sensor. Therefore, the tracking accuracy of the present invention is extremely good (typically a fraction of a degree).

The fifth objective of the present invention is to provide a collapsible solar system, which is remotely controlled by a control module, so that the user is able to remotely control the solar panel between the stored position and the tracking position without climbing up the roof of the recreation vehicle. In particularly, the remote control has its own address so that other radio emissions are rejected by the system of the present invention.

The sixth objective of the present invention is to provide a collapsible solar system, wherein the cloudy day tracking by “jogging” the horizontal movement of the solar panel to keep up with the solar movement.

The seventh objective of the present invention is to provide a collapsible solar system, which is mounted with “no hole” in the coach roof and only requires a 12 Volts DC power cable to the recreational vehicle.

For a more complete understanding of the present invention with its objectives and distinctive features and advantages, reference is now made to the following specification and to the accompanying drawings.

### BRIEF DESCRIPTION OF THE DRAWING(S)

FIG. 1 is a perspective view illustrating a collapsible solar system mounting on a roof of a recreational vehicle in accordance with the present invention.

FIG. 2 is a perspective view of the collapsible solar system in accordance with the present invention.

FIG. 3 is a perspective view of the horizontal driving unit of the collapsible solar system in accordance with the present invention.

FIG. 4 is an alternative of the horizontal driving unit of the collapsible solar system in accordance with the present invention.

FIG. 5 is a perspective view illustrating the guiding arm of the vertical driving unit to be folded flat on the solar panel of the collapsible solar system in accordance with the present invention.

FIG. 6 is a perspective view illustrating the guiding arm of the vertical driving unit being folded inclinedly on the solar panel of the collapsible solar system in accordance with the present invention.

FIG. 7 is a perspective view illustrating the solar panel being pivotally lifted up at the guiding arm of the collapsible solar system in accordance with the present invention.

FIG. 8 is a perspective view of the light sensor unit of the collapsible solar system in accordance with the present invention.

FIG. 9 is a circuit diagram of the light sensor unit of the collapsible solar system in accordance with the present invention.

FIG. 10 is a top view of the vertical driving unit of the collapsible solar system in accordance with the present invention.

FIGS. 11A to 11C illustrate the operation of the vertical driving unit of the collapsible solar system in accordance with the present invention.

### DETAILED DESCRIPTION OF THE INVENTION

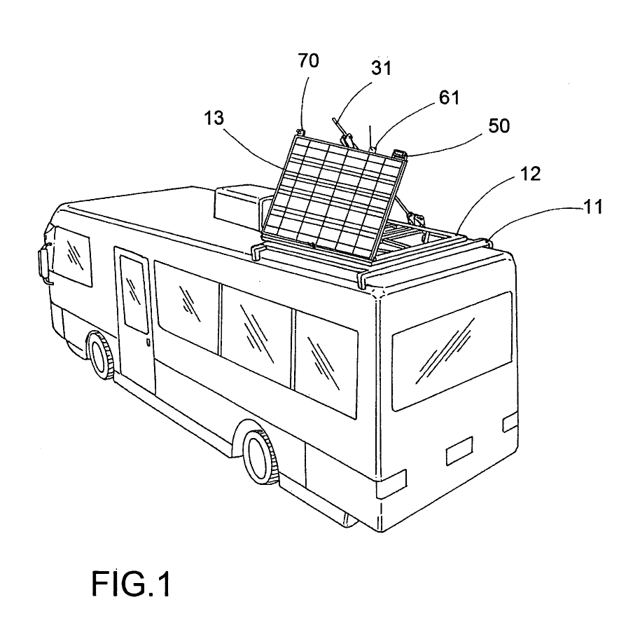

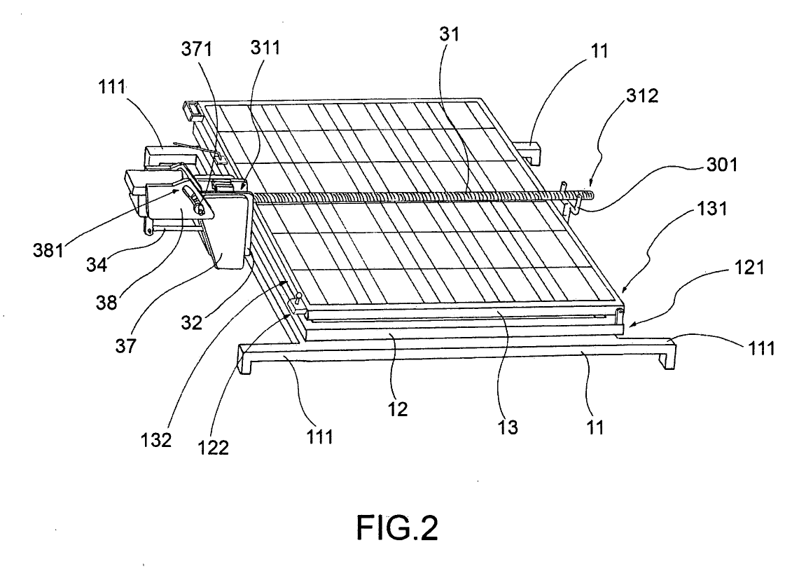

Referring to FIGS. 1 and 2, a collapsible solar system in accordance with the present invention is illustrated, wherein the collapsible solar system of the present invention is adapted for mounting on a platform collect solar energy at anytime. For simple representation and easy understanding, the collapsible solar system of the present invention is mounted on a roof of a recreational vehicle as an example. The collapsible solar system comprises a frame structure and a sunlight tracking arrangement.

As shown in FIG. 2, the frame structure comprises a supporting base 11 adapted for mounting on a roof of the recreational vehicle and a rotational frame 12 supported on the supporting base 11, wherein the rotational frame 12 has a first edge 121 and an opposed second edge 122. The frame structure further comprises a solar panel 13 having a pivot edge 131 pivotally coupling with the first edge 121 of the rotational frame 12 and an opposed controlling edge 132, wherein the solar panel 13 is adapted to pivotally fold between a stored position that the solar panel 13 is overlapped on the rotational frame 12 for being laid flat on the roof of the recreational vehicle, and a tracking position that the solar panel 13 is pivotally folded at an inclination angle to be perpendicular to the direction of the sun.

According to the preferred embodiment, the supporting base 11 is a mounting base adapted for mounting on the roof of the recreational vehicle without drilling any hole on the roof thereof. The supporting base 11 comprises a plurality of clamping arms 111 outwardly extended from the peripheral edge of the supporting base 11 for fastening at the edge of the roof of the recreational vehicle.

The rotational frame 12 is mounted on top of the supporting base 11 wherein the rotational frame 12 can be rotated on the supporting base 11 to drive the solar panel 13 in an infinite rotational movement.

The solar panel 13, which is also called as photovoltaic cell, comprises a plurality of photovoltaic cells provided at the corresponding surface of the solar panel 13 to convert the radiant energy of sunlight directly into electrical energy. Accordingly, the solar panel 13 is designed to support two 130 Watt Kyocera panels (KC-130) that a total of 260 Watts can be obtained from the sunlight.

According to the preferred embodiment, the solar panel 13 is pivotally connected to the rotational frame 12 edge-to-edge via pivot joints 120. In other words, the pivot edge 131 of the solar panel 13 is pivotally coupling with the first edge 121 of the rotational frame 12, so that the solar panel 13 can be pivotally lifted up at the inclination angle to face the photovoltaic cells towards the direction of the sun and can be pivotally dropped down to overlap on the rotational frame 12 as it is folded at the stored position. Accordingly, when the solar panel 13 is overlapped on the rotational frame 12, the solar panel 13 is folded flat on the roof of the recreational vehicle. Therefore, the solar panel 13 can be adjusted to set at the stored position during traveling.

The sunlight tracking arrangement of the collapsible solar system comprises a horizontal driving unit and a vertical driving unit for controlling the horizontal orientation and the vertical orientation of the solar panel 13 respectively.

The horizontal driving unit is arranged for driving the rotational frame 12 to be rotated on the supporting base 11 so as to selectively adjust a horizontal direction of the solar panel 13 in responsive to the direction of the sun.

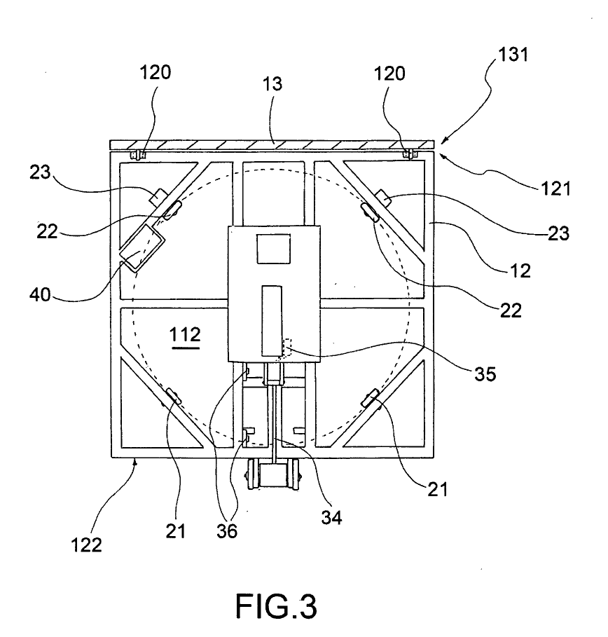

As shown in FIG. 3, the horizontal driving unit comprises a plurality of supporting wheels 21 spacedly mounted at the rotational frame 12 close to the second edge 122 thereof, a plurality of driving wheels 22 spacedly mounted at the rotational frame 12 close to the first edge 121 thereof, and a plurality of direct drive horizontal servos 23 operatively coupling with the driving wheels 22 to drive the driving wheels 22 to rotate respectively so as to rotationally turn the rotational frame 12 on the supporting base 11.

According to the preferred embodiment, the supporting base 11 has a top platform 112 for the supporting wheels 21 and the driving wheels 22 to move on the top platform 112. Therefore, when the supporting wheels 21 and driving wheels 22 are driven to move, the rotational frame 12 is rotated on the supporting base 11 to adjust the horizontal orientation of tie solar panel 13.

The supporting wheels 21 are the same as the driving wheels 22 to rotate on the top platform 112 of the supporting base 11 in a circular path. The difference between each of the supporting wheels 21 and each of the driving wheels 22 is that the direct drive horizontal servos 23 are coupled with the driving wheels 22 so that when the direct drive horizontal servos 23 are actuated to drive the driving wheels 22 to rotate, the supporting wheels 21 are driven to rotate on the top platform 112 of the supporting base 11. Accordingly, the supporting wheels 21 and the driving wheels 22 are positioned at four corner portions of the rotational frame 12 respectively so that the rotational frame 12 can be turned on the supporting base 11 in a stable manner. It is worth mentioning that the two driving wheels 22 are positioned at two corresponding corner portions of the rotational frame 12 at the first edge 121 thereof. When the solar panel 13 is pivotally lifted up at the controlling edge 132 thereof at the inclination angle, the weight of the solar panel 13 at the pivot edge 131 thereof is heavier than that of the solar panel 13 at the controlling edge 132 thereof. Therefore, the direct drive horizontal servos 23 will drive the driving wheels 22 to rotate to ensure the rotational frame 12 being turned on the supporting base 11 in a stable manner. One aspect of the present invention is that no cable is involved to drive the rotational frame 12 to turn so that the present invention does not require any retractable housing for winding any cable. In other words, the present invention can prevent the malfunction of the horizontal driving unit because the cable may be accidentally twisted up.

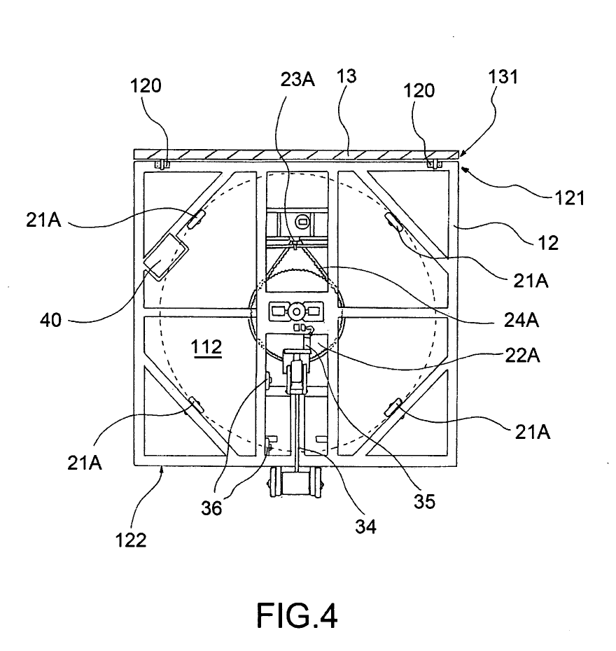

FIG. 4 illustrates an alternative of the horizontal driving unit to turn the rotational frame 12 on the supporting base 11. The alternative horizontal driving unit comprises two supporting wheels 21A positioned at four corner portions of the rotational frame 12 and a driving gear 22A supported at a center of the rotational frame 12, and a horizontal servo 23A coupling with the driving gear 22A via an endless driving chain 24A. Therefore, when the horizontal servo 23A is actuated to drive the driving gear 22A to rotate via the driving chain 24A the rotational frame 12 is turned on the supporting base 11. Thus, no cable is involved to drive the rotational frame 12 to turn.

The vertical driving unit is arranged for pivotally lifting up the solar panel 13 at the controlling edge 132 thereof until the solar panel 13 is pivotally folded at the inclination angle to be perpendicular to the direction of the sun. The vertical driving unit is also arranged for pivotally dropping down the solar panel 13 at the controlling edge 132 thereof until the solar panel 13 is pivotally folded to overlap on the rotational frame 12 at the stored position.

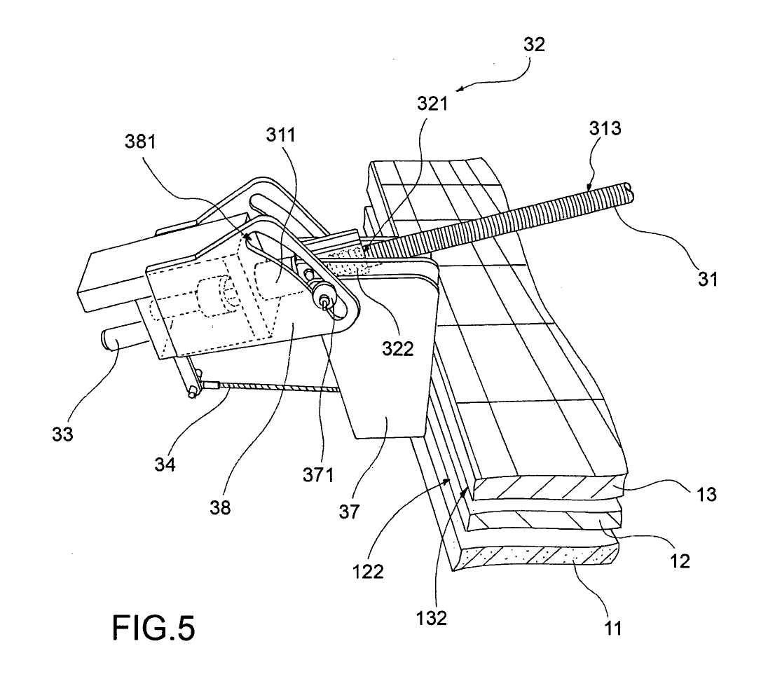

As shown in FIGS. 5 to 7, the vertical driving unit comprises an elongated guiding arm 31, a panel driver 32, a vertical servo 33, and means 34 for controlling the guiding arm 31 at the inclined manner.

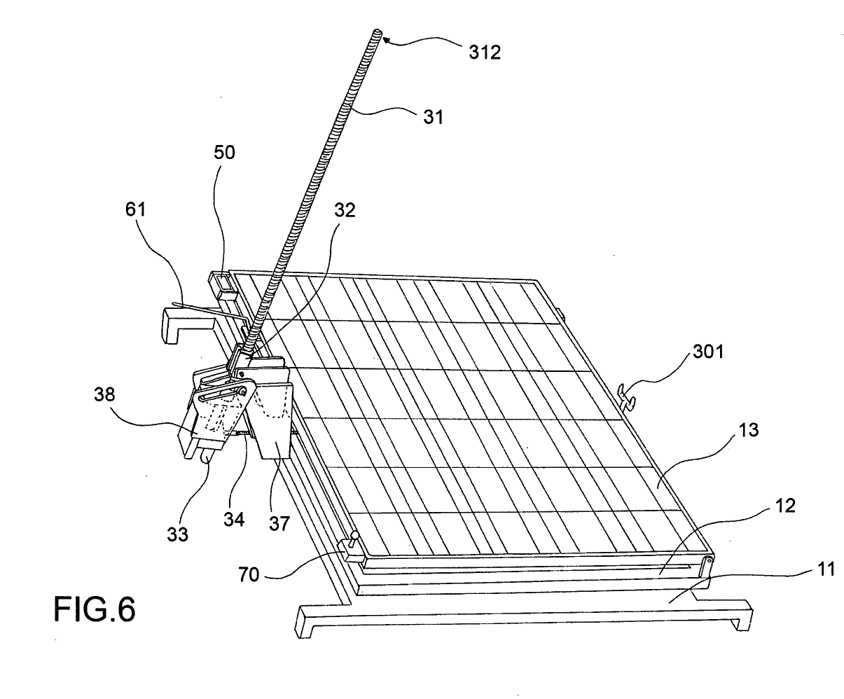

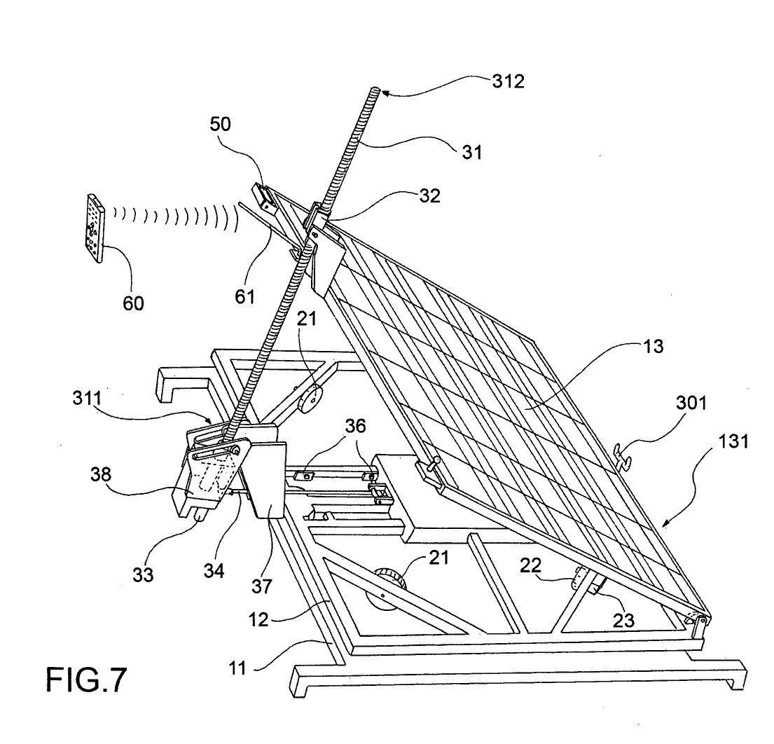

The guiding arm 31 has a pivot end 311 pivotally coupling with the second edge 122 of the rotational frame 12 and a free end 312 extended above the solar panel 13. As shown in FIG. 2, at the stored position of the solar panel 13, the guiding arm 31 is horizontally supported above the solar panel 13. Therefore, the guiding arm 31 can be also folded flat on the solar panel 13 for transport At the tracking position of the solar panel 13, the guiding arm 31 is pivotally lifted up at the pivot end 311 to extend at an inclined configuration, as shown in FIG. 6, so that the controlling edge 132 of the solar panel 13 is guided to slide along the inclined guiding arm 31 so as to selectively adjust the inclination angle of the solar panel 13. Therefore, once the guiding arm 31 is extended at an inclined configuration, the solar panel 13 can be pivotally lifted up at the direction from the pivot end 311 of the guiding arm 31 towards the free end 312 thereof, as shown in FIG. 7. It is worth mentioning that when the guiding arm 31 is horizontally supported above the solar panel 13, i.e. the stored position of the solar panel 13, the solar panel 13 is at an idle position that the solar panel 13 cannot be pivotally lifted up. Preferably, the guiding arm 31 being folded not more that 90° from its horizontal configuration.

The guiding arm 31 is also used as a supporting post to support the weight of the solar panel 13 at the inclination angle. When the solar panel 13 is pivotally lifted up along the guiding arm 31, the solar panel 13 and the guiding arm 31 form a triangular structure so that the solar panel 13 can be securely retained at the inclination position in a stable manner.

The vertical driving unit further comprises an arm seat 301 perpendicularly extended from the solar panel 13 at the pivot edge 131 thereof to align with the guiding arm 31. Accordingly, when the guiding arm 31 is pivotally lowered at its horizontal position above the solar panel 13, the free end 312 of the guiding arm 31 is supported by the arm seat 301 to retain the guiding arm 31 in position. The arm seat 301 comprises a seat base extended from the pivot edge 131 of the solar panel 13 and a U-shaped seat member extended from the seat base to receive the free end 312 of the guiding arm 31 within the seat member.

The panel driver 32 is pivotally coupling with the controlling edge 132 of the solar panel 13 and is slid along the guiding arm 31 to pivotally lift up and drop down the controlling edge 132 of the solar panel 13. As shown in FIG. 5, the panel driver 32 forms a coupling joint to couple the controlling edge 132 of the solar panel 13 with the guiding arm 31. Therefore, when the controlling edge 132 of the solar panel 13 is lifted upwardly, tie panel driver 32 is pivotally moved at the controlling edge 132 of the solar panel 13 to slide along the guiding arm 31.

For controllably adjusting the inclination angle of the solar panel 13, the guiding arm 31 has an outer threaded portion 313 provided between the pivot end 131 and the free end 132. The panel driver 32 has a sliding slot 321 for the guiding arm 31 passing therethrough and a corresponding inner threaded portion 322 which is provided at an inner wall of the sliding slot 321 and is engaged with the outer threaded portion 313 of the guiding arm 31. Therefore, the rotational movement of the guiding arm 31 will drive the solar panel 13 to be lifted up or dropped down. In particularly, when the guiding arm 31 is rotated at one direction, the panel driver 32 is driven to slidably move towards the free end 312 of the guiding arm 31 so as to pivotally lift up the solar panel 13, and when the guiding arm 31 is rotated at an opposed direction, the panel driver 32 is driven to slidably move towards the pivot end 311 of the guiding arm 31 so as to pivotally drop down the solar panel 13.

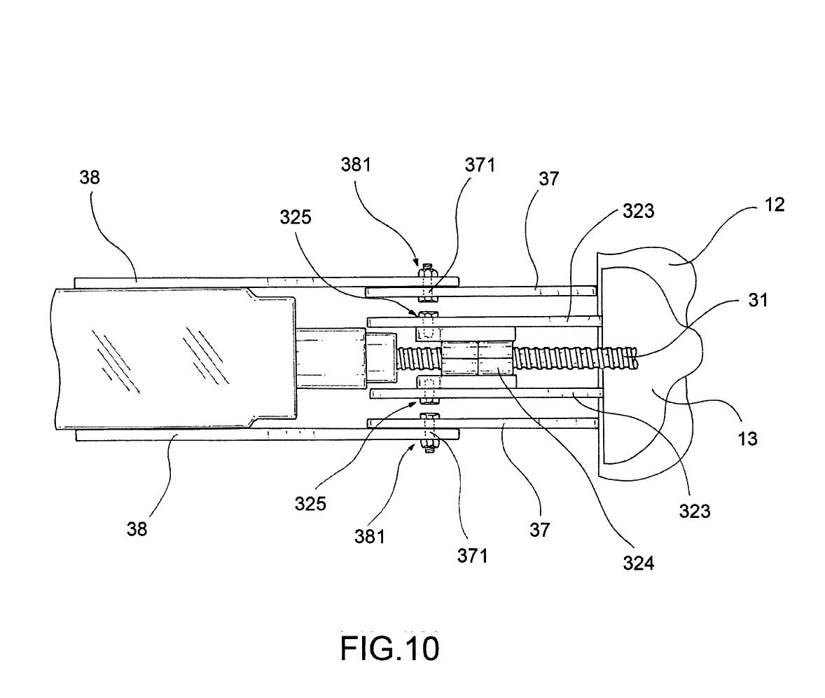

Accordingly, the panel driver 32 comprises two side brackets 323 affixed to the controlling edge 132 of the solar panel 13 and an arm slider 324 pivotally coupling between the side brackets 321 via a pivot point 325 to slidably couple with the guiding arm 31, as shown in FIG. 10. The arm slider 324 is embodied as a follower nut that the sliding slot 321 is provided at the arm slider 324 for the guiding arm 31 slidably passing through the arm slider 324. Therefore, when the guiding arm 31 is driven to rotate, the arm slider 324 is rotated along the guiding arm 31 to raise or lower the solar panel 13.

The vertical servo 33 is arranged to drive the guiding arm 31 to rotate. The vertical servo 33 is coupling at the pivot end 311 of the guiding arm 31 to drive the guiding arm 31 to rotate via a gear unit, wherein when the guiding arm 31 is retained in an inclined manner, the guiding arm 31 is driven to rotate via the vertical servo 33 to drive the panel driver 32 to slidably move along the guiding arm 31 so as to pivotally lift up the solar panel 13 at the controlling edge 132 thereof until the solar panel 13 is pivotally folded at the inclination angle to be perpendicular to the direction of the sun. It is worth mentioning that the solar panel 13 will be automatically lowered to reduce wind loading during the high wind condition.

The control means comprises a control arm 34 is supported at the rotational frame 12 and is coupled with the pivot end 311 of the guiding arm 31, and a control servo 35 driving the control arm 34 in a linear direction. The control servo 35 is actuated to slidably pull and push the control arm 34. When the control arm 34 is pulled, the guiding arm 31 is pulled at the pivot end 311 thereof so that the guiding arm 31 is pivotally lifted up white the panel driver 32 is correspondingly lifted up. When the control arm 34 is pushed, the guiding arm 31 is pushed at the pivot end 311 thereof so that the guiding arm 31 is pivotally dropped down.

The control means further comprises two linear traveling sensors 36, as shown in FIG. 3, spacedly mounted at the rotational frame 12 for detecting a linear traveling distance of the control arm 34 to determine the inclination angle of the guiding arm 31. Accordingly, the linear traveling distance of the control arm 34 is measured to determine the inclination angle of guiding arm 31 to guide elevation of the solar panel 13. At the initial position of the control arm 34, i.e. the linear traveling distance of the control arm 34 is set as zero, the guiding arm 31 is horizontally supported above the solar panel 13 at the stored position. By increasing the linear traveling distance of the control arm 34, the inclination angle of the guiding arm 31 is proportionally increased.

The vertical driving unit further comprises a housing joint coupling the rotational frame 12 with the pivot end 311 of the guiding arm 31. The housing joint comprises a first housing 37 affixed to the second edge 122 of the rotational frame 12 and a second housing 38 which is pivotally coupled with the first housing 37 and is securely housing with the pivot end 311 of the guiding aim 31. As shown in FIG. 5, the first housing 37 has two pivot protrusions 371 outwardly protruded from two sidewalls of the first housing 37 respectively whole the second housing 38 has two arc-shaped slot 381 formed at two sidewalls of the first housing 37 respectively, wherein the pivot protrusions 371 are engaged with the arc-shaped slot 381 when the sidewalls of the second housing 38 are overlapped on the sidewalls of the first housing 37 respectively so that the second housing 38 can pivotally moved with respect to the first housing 37. The two pivot protrusions 371 can be selectively adjusted at the position along the two arc-shaped slots 381 to adjust the pivotal movement between the first and second housings 37 and 38.

The control arm 34 is pivotally coupled with the second housing 38 via an elongated extension arm 39 at a control point 391 to control the pivot end 311 of the guiding aim 31. Accordingly, the arc-shaped slot 381 is the load bearing surface with bearings running inside the arc-shaped slot 381 to support the weight of the solar panel 13. As the solar panel 13 raises and lowers, the bearing moves within the arc-shaped slot 381 correspondingly. Therefore, when the control arm 34 is actuated to pivotally lift up and drop down the guiding arm 31 with the panel driver 32, the second housing 38 is correspondingly driven to pivotally move along the arc-shaped slot 381. Once the guiding arm 31 is set at an inclined configuration, preferably 45 degree inclination, the guiding arm 31 and the control arm 34 are stationary stopped at this position for adjustably elevating the solar panel 13 along the guiding arm 31.

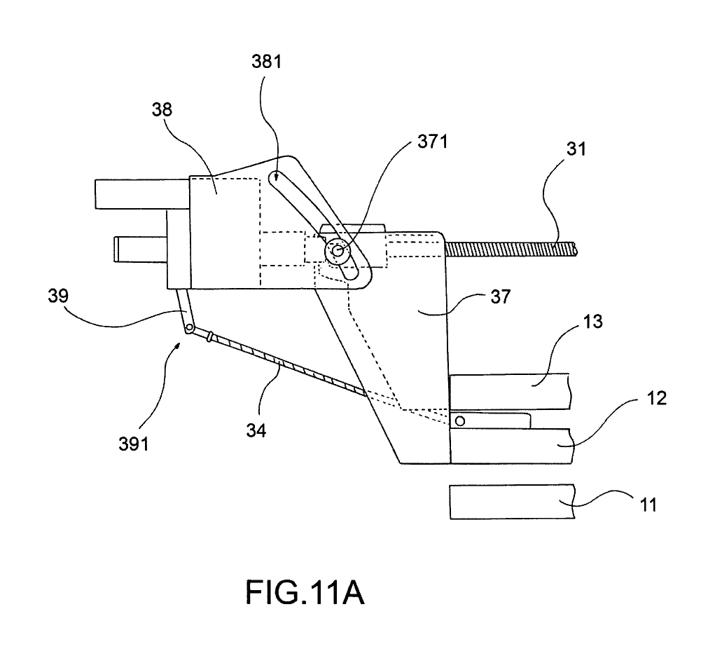

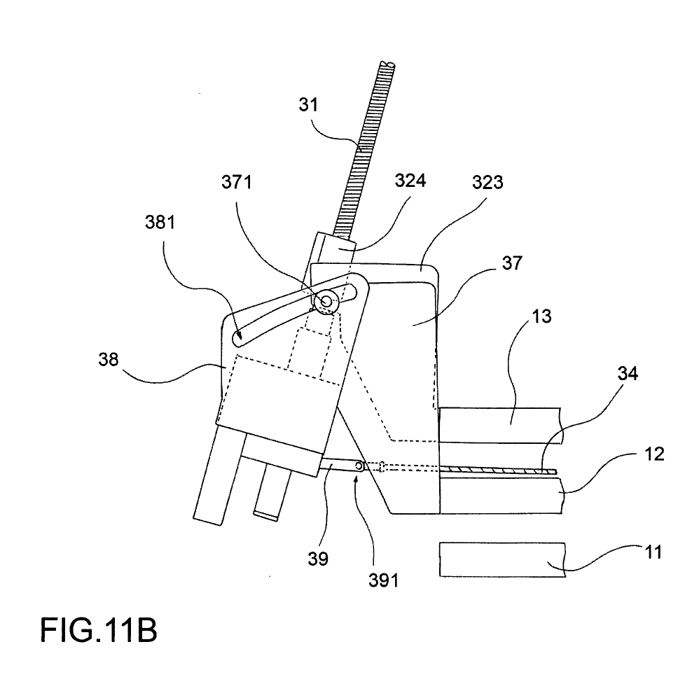

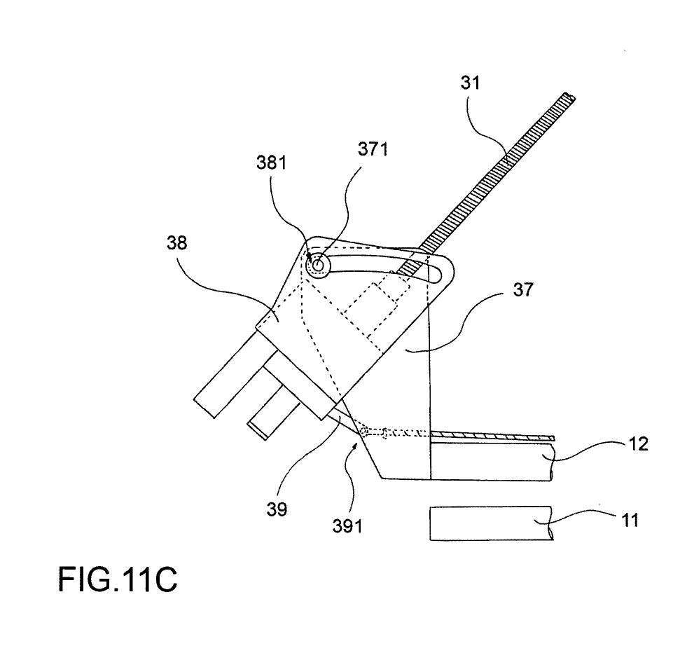

FIG. 11A illustrates the guiding arm 31 being folded flat on top of the solar panel 13, wherein the pivot protrusions 371 are positioned close to two inner ends of the arc-shaped slots 331. When the control arm 34 is pulled to pivotally raise the guiding arm 31, the control point 391 is moved towards the rotational frame 12, as shown in FIG. 11B. At this moment, the pivot protrusions 371 are still positioned close to two inner ends of the arc-shaped slots 381. It is worth mentioning that the pivot protrusions 371 are aligned with the pivot point 325 at the same axis as shown in FIG. 10. Therefore, the control point 391 is moved along a curved path with respect to the axis of the pivot protrusions 371. In other words, the pivot point 325 is the center of the traveling path of the control point 391 to move when the control arm 34 is pulled to pivotally raise the guiding arm 31.

Once the guiding arm 31 is pivotally raised at a predetermined inclination angle, the solar panel 13 is ready to lift up via the panel drive 32. During the solar panel 13 is being lifted up, the second housing 38 is started to move to support the weight of the solar panel 13 at the inclination angle. Accordingly, the pivot protrusions 371 are moved towards two outer ends of the arc-shaped slots 381 during the solar panel 13 is being lifted up at its maximum vertical position as shown in FIG. 11C. When the solar panel 13 is elevated to increase its inclination angle, i.e. the solar panel 13 is moving towards its vertical position, the pivot protrusions 371 are moved towards the outer ends of the arc-shaped slots 381. Likewise, when the solar panel 13 is elevated to reduce its inclination angle, i.e. the solar panel 13 is moving towards its horizontal position, the pivot protrusions 371 are moved towards the inner ends of the arc-shaped slots 381.

It is worth mentioning that the control point 291 is stayed at the same position after the guiding arm 31 is lifted up, such that the control point 291 becomes a stationary point after the guiding arm 31 is elevated. Therefore, the control point 291 is located at the same position as shown in FIGS. 11B and 11C.

According to the preferred embodiment, the length of the arc-shaped slot 381 will limit the inclination angle of the solar panel 13 after the guiding arm 31 is elevated. As it is mentioned above, the pivot protrusions 371 are moved towards the inner ends of the arc-shaped slots 381 when the solar panel 13 is folded flat at its horizontal position, as shown in FIG. 11B. The pivot protrusions 371 are moved towards the outer ends of the arc-shaped slots 381 when the solar panel is folded at its vertical position, as shown in FIG. 11C. Accordingly, the inner ends of the arc-shaped slots 381 are two ends positioned closed to the solar panel 13 while the outer ends of the arc-shaped slots 381 are two ends positioned away from the solar panel 13.

The vertical servo 33 is housed in the second housing 38 for protection. Thus, the panel driver 32 is housed in the first housing 37 when the solar panel 13 is set at the stored position.

The sunlight tracking arrangement further comprises a control module 40 operatively controlling the horizontal and vertical driving units. The control module 40 comprises a 40 pin microprocessor embedded machine controller with firmware in machine language for extremely high speed. Once the control module 40 is activated, the horizontal and vertical driving units are actuated to him the rotational frame 12 and to pivotally lift up the solar panel 13 respectively to track the sunlight. It is worth mentioning that the control module 40 is electrically connected to the 12 Volts DC power from the recreational vehicle for operation.

The sunlight tracking arrangement further comprises a light sensing module 50 provided at the controlling edge 132 of the solar panel 13 to detect the direction of the sun. Accordingly, when the control module 40 receives a control signal from the light sensing module 50, the control module 40 automatically controls the horizontal and vertical driving units to move the solar panel 13 until the solar panel 13 is pivotally folded to be perpendicular to the direction of the sun.

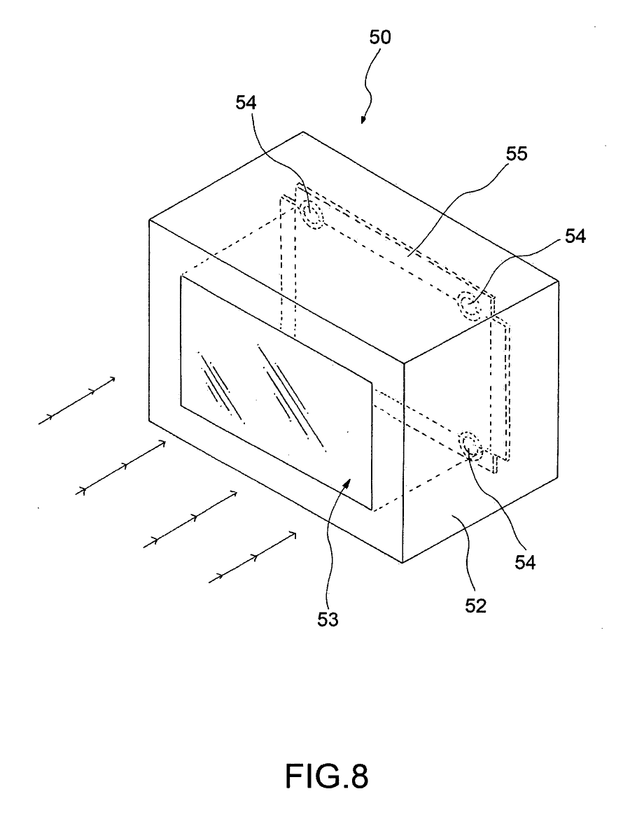

As shown in FIG. 8, the light sensing module 50 is mounted at a corner portion of the solar panel 13 along the controlling edge 132 thereof. The light sensing module 50 comprises a sensor housing 52 having an aperture 53 for enabling sunlight passing through the aperture 53 into the interior cavity of the sensor housing 52. The light sensing module 50 further comprises four light sensors 54 received in the sensor housing 52 to partially align with the aperture 53, so that when the solar panel 13 is facing directly to the sun, each of the light sensors 54 is half illuminated for accurately adjust an alignment of the solar panel 13 with respect to the direction of the sun. A dark Plexiglas is provided at the aperture 53 to enclose the interior cavity of the sensor housing 52 and to reduce sunlight level so the sensor cells operate on the linear portion of their sensitivy curve, wherein a metal back plate is provided behind the light sensors 54. Accordingly, the control signal from the light sensing module 50 are the four light levels of the light sensor 54 in terms of voltages.

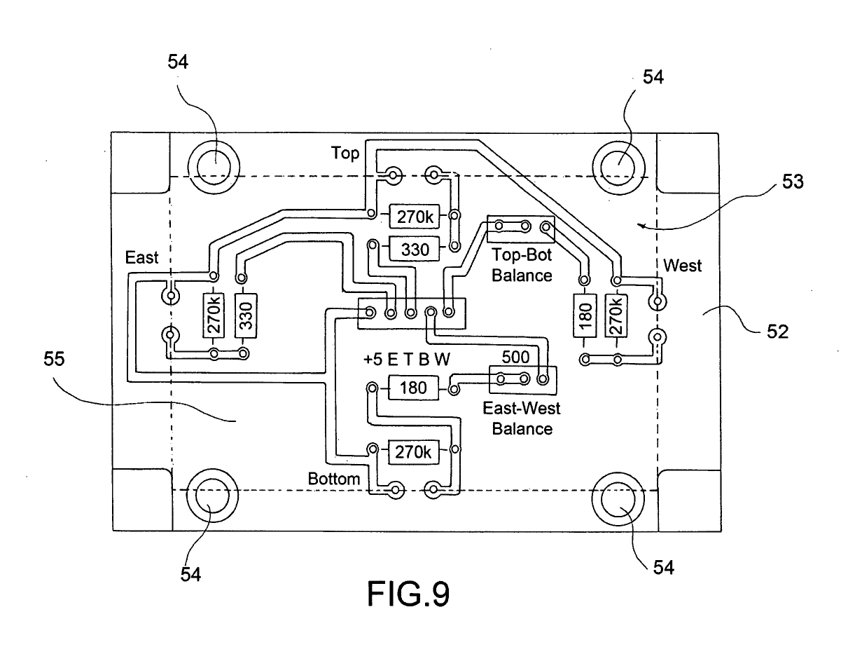

FIG. 9 illustrates the circuit diagram of the light sensing module 50. According to the preferred embodiment, four light sensors 54 are electrically mounted on the circuit board 55 at four corner portions thereof respectively. When the aperture 53 of the sensor housing 52 is directly aligned with the direction of the sun, each of the light sensors 54 is partially illuminated and is partially shaded by the sensor housing 43. Preferably, each light sensor 54 is half illuminated and is half shaded by the sensor housing 43. Therefore, by detecting and comparing the light intensity of each of the light sensors 54, the control module 40 automatically controls the horizontal and vertical driving units to precisely move the solar panel 13 until the solar panel 13 is pivotally folded to be perpendicular to the direction of the sun.

Each of the light sensors 54 is a photo sensor mounted on the circuit board 55 behind the rectangle aperture 53 which when on axis allows sunlight to fall on half of each light sensor 54. The four lighter sensors 54 are two on the vertical plane and two on the horizontal plane. The is designed so that as the sun “move”, one light sensor 54 experiences increased illumination and the other light sensor 54 experiences reduced illumination with respect to each plane. This doubles the “system gain” and therefore increases the resolution of tracking to be “razor sharp”.

The collapsible solar system further comprises a remote controller 60 wirelessly controlling the sunlight tracking arrangement at an “off” mode that the horizontal driving unit and the vertical driving unit are deactivated to retain the solar panel 13 at its halt position, and at an “operative” mode that the horizontal driving unit and the vertical driving unit are activated at a “resume tracking mode” to start actuating the solar panel 13 for tracking the direction of the sun. It is worth mentioning that the remote controller 60 has its own RF address so that other radio emissions are rejected by the remote controller 60 for prevent the RF interference. A RF antenna 61 is mounted at the controlling edge 132 of the solar panel 13 to wirelessly connect with the remote controller via radio frequency.

Accordingly, light sensing module 50 uses several light level threshold levels and time values which are stored in non-volatile memory of the control microprocessor. These values may be loaded in using a terminal connected directly to the circuit board via RS232 connection or the same terminal may be connected to the remote controller 60 and parameters read and loaded remotely without accessing the roof of the recreational vehicle.

According to the preferred embodiment, the operation of the collapsible solar system comprises the following steps.

(1) Raise the guiding arm 31 at the inclined configuration from its initial position, wherein at the initial position, the guiding arm 31 is horizontally supported above the solar panel 13.

(2) Raise the solar panel 13 to 45 degree inclination.

(3) Manually control the orientation of the solar panel 13 by the operator, wherein the operator remotely controls the horizontal servo 23 and the vertical servo 33 to roughly align the solar panel 13 to be perpendicular to the direction of the sun.

(4) Remotely initiate the “auto tracking” that the solar panel 13 is automatically tracked the direction of the sun via the light sensing module 50.

A visual pointer 70 is mounted at the controlling edge 132 of the solar panel 13 to point at the direction of the sun. The user is able to operate the remote controller 60 to manually control the horizontal driving unit and the vertical driving unit until the solar panel 13 is moved to be perpendicular to the direction of the sun. The visual pointer 70 is extended perpendicularly to tile solar panel 13 so that the user is able to use the visual pointer 70 to get the direction of the sun.

According to the preferred embodiment, sunlight is sensed by the light sensing module 50 which is used to digitize light levels within the control module 40. Once in numeric form, all tracking decisions are made based on the sun direction and light intensity. At the end of the tracking day, the control module 40 lowers the solar panel 13 to the horizontal position (the solar panel 13 is perpendicular to the roof) and rotates horizontally to the “East” waiting for the sun to rise as the “sleep” position. In addition, the collapsible solar system of the present invention tracks the sun both during clear and cloudy days. When the light level diminishes due to clouds, vertical tracking is locked out to inhibit unnecessary “all over the sky” tracking. It the light level continues to drop with increased clouds, the horizontal active tracking is inhibited. At this point in tracking heavy cloudy conditions, the horizontal tracking reverts to a “horizontal” jog at the appropriate duration and period to keep up with the sun. When the sun “breakout” occurs, the collapsible solar system is pointing in the vicinity of the sun and again “locks” onto the sun both horizontally and vertically. At first light in the morning, the collapsible solar system is automatically activated as a “wake up” mode to track horizontally and vertically on a one time basis with no light threshold limits. The “wake up” mode is employed to eliminate tracking to undesirable lights at night. In the event of extremely windy conditions, the vertical tracking may be inhibited and the solar panel 13 is lowered to a “safe” elevation via the remote controller 60. The collapsible solar system will track on a horizontal basis only as long as the collapsible solar system is left in this mode.

When the collapsible solar system is deployed via the remote controller 60, the first step is to raise the guiding arm 31 to its operating position with the control arm 34. Once in the operating position, the vertical servo 33 is actuated and the solar panel 13 is elevated to about at 45° elevation. At this point, the collapsible solar system ceases operation and is in “standby” mode awaiting the manual horizontal and vertical driving unit commands to find the sun. This can be accomplished via the remote controller 60. Once the shadow falls on the target, the collapsible solar system is ready for “resume” tracking. The collapsible solar system now will be in automatic tracking and can be left unattended for solar panel optimum tracking.

When the user wishes to store the solar panel 13 far transport, the remote controller 60 is activated to turn the sunlight tracking arrangement at a “store” mode. In particularly, the remote controller 60 is operated to set the solar panel 13 at the “store panel” within the menu displayed on the remote controller 60. The control processor of the remote controller 60 upon receiving the “store panel” command rotates the rotational frame 12 to the “indexed” position and then lowers the solar panel 13 to the stored position. Then, the guiding arm 31 is lowered down over the top of the solar panel 13 and the stored operation is completed. The remote controller 60 can be turned off after the stored operation is completed.

In view of the present invention, the radiant energy of sunlight can be efficiently collected and directly converted into electrical energy to be stored in a battery. The collapsible solar system of the present invention is adapted to automatically adjust the horizontal and vertical orientations of the solar panel 13 to be perpendicular to the direction of the sun, so that the solar panel 13 can collect maximized radiant energy of sunlight. The collapsible solar system automatically tracks the sun when the sun “moves” at the day time and automatically set the sunlight tracking arrangement to be stored during the night time. It is worth mentioning that the collapsible solar system can be incorporated with all residential or commercial buildings. However, having the fold-flat structure of the solar panel 13, the collapsible solar system is perfect to incorporate with the recreational vehicle especially during transporting.

Accordingly, the collapsible solar system is shown to be incorporated with the recreational vehicle to illustrate the best mode of the present invention, in which the solar panel 13 is folded flat on the roof of the recreational vehicle. However, it would nave been obvious that the collapsible solar system can be incorporated with the boats, trucks, cars, residential, industrial and commercial buildings, trains, and hot air balloons for supplying electrical energy converted from the solar energy.

While the embodiments and alternatives of the present invention have been shown and described, it will be apparent to one skilled in the art that various other changes and modifications can be made without departing from the spirit and scope of the present invention.

What is claimed is:

1. A collapsible solar system, comprising:
a supporting base adapted for mounting on a platform;
a rotational frame supported on said supporting base, wherein said rotational name has a first edge and an opposed second edge;
a solar panel having a pivot edge pivotally coupling with said first edge of said rotational frame and an opposed controlling edge, wherein said solar panel is adapted to pivotally fold between a stored position that said solar panel is overlapped on said rotational frame for being laid flat on said platform, and a tracking position that said solar panel is pivotally folded at an inclination angle to be perpendicular to the direction of the sun; and
a sunlight tracking arrangement, comprising:
a horizontal driving unit driving said rotational frame to be rotated on said supporting base so as to selectively adjust a horizontal direction of said solar panel in responsive to the direction of the sun; and
a vertical driving unit pivotally lifting up said solar panel at said controlling edge thereof until said solar panel is pivotally folded at said inclination angle to be perpendicular to the direction of the sun, and pivotally dropping down said solar panel at said controlling edge thereof until said solar panel is pivotally folded to overlap on said rotational frame at said stored position.

2. The collapsible solar system of claim 1 wherein said vertical driving unit comprises an elongated guiding arm having a pivot end pivotally coupling with said second edge of said rotational frame and a free end extended above said solar panel, wherein at said stored position of said solar panel, said guiding arm is horizontally supported above said solar panel, and at said tracking position of said solar panel, said guiding arm is pivotally lifted up at said pivot end to extend at an inclined configuration, so that said controlling edge of said solar panel is guided to slide along said inclined guiding arm so as to selectively adjust said inclination angle of said solar panel.

3. The collapsible solar system of claim 2 wherein said vertical driving unit further comprises a panel driver pivotally coupling with said controlling edge of said solar panel and being slid along said guiding arm to pivotally lift up and drop down said controlling edge of said solar panel.

4. The collapsible solar system of claim 3 wherein said guiding arm has an outer threaded portion provided between said pivot end and said free end, wherein said panel driver has a sliding slot for said guiding arm passing therethrough and an inner threaded portion which is provided at an inner wall of said sliding slot and is engaged with said outer threaded portion of said guiding arm, so that when said guiding arm is rotated at one direction, said panel driver is driven to slidably move towards said free end of said guiding arm so as to pivotally lift up said solar panel, and when said guiding arm is rotated at an opposed direction, said panel driver is driven to slidably move towards said pivot end of said guiding arm so as to pivotally drop up said solar panel.

5. The collapsible solar system of claim 4 wherein said vertical driving unit further comprises a vertical servo coupling at said pivot end of said guiding arm to drive said guiding arm to rotate, wherein when said guiding arm is retained in an inclined manner, said guiding arm is driven to rotate via said vertical servo to drive said panel driver to slidably move along said guiding arm so as to pivotally lift up said solar panel at said controlling edge thereof until said solar panel is pivotally folded at said inclination angle to be perpendicular to the direction of the sun.

6. The collapsible solar system of claim 2 wherein said vertical driving unit further comprises a control arm which is supported at said rotational frame and is coupled with said pivot end of said guiding arm, and a control servo driving said control arm in a linear direction to slidably pull and push said control arm for pivotally lifting up and dropping down said guiding arm respectively.

7. The collapsible solar system of claim 5 wherein said vertical driving unit further comprises a control arm which is supported at said rotational frame and is coupled with said pivot end of said guiding arm, and a control servo driving said control arm in a linear direction to slidably pull and push said control arm for pivotally lifting up and dropping down said guiding arm respectively.

8. The collapsible solar system of claim 6 wherein said vertical driving unit further comprises two linear traveling sensors spacedly mounted at said rotational frame for detecting a linear traveling distance of said control arm to determine said inclination angle of said guiding arm.

9. The collapsible solar system of claim 7 wherein said vertical driving unit further comprises two linear traveling sensors spacedly mounted at said rotational frame for detecting a linear traveling distance of said control arm to determine said inclination angle of said guiding arm.

10. The collapsible solar system of claim 1 wherein said sunlight tracking arrangement further comprises a control module operatively controlling said horizontal and vertical driving units, and a light sensing module provided at said controlling edge of said solar panel to detect the direction of the sun, so that when said control module receives a control signal from said light sensing module, said control module automatically controls said horizontal and vertical driving units to move said solar panel until said solar panel is pivotally folded to be perpendicular to the direction of the sun.

11. The collapsible solar system of claim 5 wherein said sunlight tracking arrangement further comprises a control module operatively controlling said horizontal and vertical driving units, and a light sensing module provided at said controlling edge of said solar panel to detect the direction of the sun, so that when said control module receives a control signal from said light sensing module, said control module automatically controls said horizontal and vertical driving units to move said solar panel until said solar panel is pivotally folded to be perpendicular to the direction of the sun.

12. The collapsible solar system of claim 9 wherein said sunlight tracking arrangement further comprises a control module operatively controlling said horizontal and vertical driving units, and a light sensing module provided at said controlling edge of said solar panel to detect the direction of the sun, so that when said control module receives a control signal from said light sensing module, said control module automatically controls said horizontal and vertical driving units to move said solar panel until said solar panel is pivotally folded to be perpendicular to the direction of the sun.

13. The collapsible solar system of claim 10 wherein said light sensing module comprises one or more light sensor units spacedly mounted at two corner portions of said solar panel along said controlling edge thereof respectively, wherein each of said light sensor units comprises a sensor housing having an aperture, and two or more light sensors received in said sensor housing to partially align with said aperture, so that when said solar panel is facing to the sun, each of said light sensors is half illuminated for accurately adjust an alignment of said solar panel with respect to the direction of the sun.

14. The collapsible solar system of claim 11 wherein said light sensing module comprises one or more light sensor units spacedly mounted at two corner portions of said solar panel along said controlling edge thereof respectively, wherein each of said light sensor units comprises a sensor housing having an aperture, and two or more light sensors received in said sensor housing to partially align with said aperture, so that when said solar panel is facing to the sun, each of said light sensors is half illuminated for accurately adjust an alignment of said solar panel with respect to the direction of the sun.

15. The collapsible solar system of claim 12 wherein said light sensing module comprises one or more light sensor units spacedly mounted at two corner portions of said solar panel along said controlling edge thereof respectively, wherein each of said light sensor units comprises a sensor housing having an aperture, and two or more light sensors received in said sensor housing to partially align with said aperture, so that when said solar panel is facing to the sun, each of said light sensors is half illuminated for accurately adjust an alignment of said solar panel with respect to the direction of the sun.

16. The collapsible solar system of claim 1 wherein said horizontal driving unit comprises a plurality of supporting wheels spacedly mounted at said rotational frame dose to said second edge thereof, a plurality of driving wheels spacedly mounted at said rotational frame close to said first edge thereof, and a plurality of direct drive horizontal servos operatively coupling with said driving wheels to drive said driving wheels to rotate respectively so as to rotationally turn said rotational frame on said supporting base.

17. The collapsible solar system of claim 5 wherein said horizontal driving unit comprises a plurality of supporting wheels spacedly mounted at said rotational frame close to said second edge thereof, a plurality of driving wheels spacedly mounted at said rotational frame close to said first edge thereof, and a plurality of direct drive horizontal servos operatively coupling with said driving wheels to drive said driving wheels to rotate respectively so as to rotationally turn said rotational frame on said supporting base.

18. The collapsible solar system of claim 15 wherein said horizontal driving unit comprises a plurality of supporting wheels spacedly mounted at said rotational frame dose to said second edge thereof, a plurality of driving wheels spacedly mounted at said rotational frame close to said first edge thereof, and a plurality of direct drive horizontal servos operatively coupling with said driving wheels to drive said driving wheels to rotate respectively so as to rotationally turn said rotational frame on said supporting base.

19. The collapsible solar system of claim 1 further comprising a remote controller wirelessly controlling said sunlight tracking arrangement at an “off” mode that said horizontal driving unit and said vertical driving unit are deactivated to retain said solar panel at its halt position, and at an “operative” mode that said horizontal driving unit and said vertical driving unit are activated at a “resume tracking mode” to start actuating said solar panel for tracking the direction of the sun.

20. The collapsible solar system of claim 5 further comprising a remote controller wirelessly controlling said sunlight tracking arrangement at an “off” mode that said horizontal driving unit and said vertical driving unit are deactivated to retain said solar panel at its halt position, and at an “operative” mode that said horizontal driving unit and said vertical driving unit are activated at a “resume tracking mode” to start actuating said solar panel for tracking the direction of the sun.

21. The collapsible solar system of claim 18 further comprising a remote controller wirelessly controlling said sunlight tracking arrangement at an “off” mode that said horizontal driving unit and said vertical driving unit are deactivated to retain said solar panel at its halt position, and at an “operative” mode that said horizontal driving unit and said vertical driving unit are activated at a “resume tracking mode” to start actuating said solar panel for tracking the direction of the sun.

22. The collapsible solar system of claim 7 wherein said vertical driving unit further comprises a first housing affixed to said second edge of said rotational frame and a second housing which is pivotally coupled with said first housing and is securely housing with said pivot end of said guiding arm, wherein two pivot protrusions of said first housing is slidably engaged with two arc-shaped slots of said second housing respectively, wherein said pivot protrusions are aligned with a pivot point of said panel driver when said guiding arm is pivotally lifted up from its horizontal position to its inclined position, wherein said pivot protrusions are slid from inner ends of said arc-shaped slots to outer ends thereof when said solar panel is pivotally lifted up from its stored position to its tracking position.

23. The collapsible solar system of claim 15 wherein said vertical driving unit further comprises a first housing affixed to said second edge of said rotational frame and a second housing which is pivotally coupled with said first housing and is securely housing with said pivot end of said guiding arm, wherein two pivot protrusions of said first housing is slidably engaged with two arc-shaped slots of said second housing respectively, wherein said pivot protrusions are aligned with a pivot point off said panel driver when said guiding arm is pivotally lifted up from its horizontal position to its inclined position, wherein said pivot protrusions are slid from inner ends of said arc-shaped slots to outer ends thereof when said solar panel is pivotally lifted up from its stored position to its tracking position.

24. The collapsible solar system of claim 21 wherein said vertical driving unit further comprises a first housing affixed to said second edge off said rotational frame and a second housing which is pivotally coupled with said first housing and is securely housing with said pivot end of said guiding arm, wherein two pivot protrusions of said first housing is slidably engaged with two arc-shaped slots of said second housing respectively, wherein said pivot protrusions are aligned with a pivot point of said panel driver when said guiding arm is pivotally lifted up from its horizontal position to its inclined position, wherein said pivot protrusions are slid from inner ends of said arc-shaped slots to outer ends thereof when said solar panel is pivotally lifted up from its stored position to its tracking position.

25. The collapsible solar system of claim 15 wherein said horizontal driving unit comprises four spaced apart supporting wheels mounted at said rotational frame, a driving gear supported at a center of said rotational frame, and a horizontal servo coupling with said driving gear via an endless driving chain, so that when said horizontal servo is actuated to drive said driving gear to rotate via said driving chain, said rotational frame is turned on said supporting base.

26. The collapsible solar system of claim 25 further comprising a remote controller wirelessly controlling said sunlight tracking arrangement at an “off” mode that said horizontal driving unit and said vertical driving unit are deactivated to retain said solar panel at its halt position, and at an “operative” mode that said horizontal driving unit and said vertical driving unit are activated at a “resume tracking mode” to start actuating said solar panel for tracking the direction of the sun.
